(19) United States
(12) Patent Application Publication
(10) Pub. No.: US 2026/0053068 A1
(43) Pub. Date: Feb. 19, 2026

(54) SEMICONDUCTOR PACKAGE INCLUDING AN EMI SHIELD

(71) Applicant: SAMSUNG ELECTRONICS CO., LTD., SUWON-SI (KR)

(72) Inventors: Keunyoung Lee, Suwon-si (KR); Dongok Kwak, Suwon-si (KR); Eunhye Lee, Suwon-si (KR); Taeyoung Lee, Suwon-si (KR)

(21) Appl. No.: 19/175,605

(22) Filed: Apr. 10, 2025

(30) Foreign Application Priority Data
Aug. 14, 2024 (KR) 10-2024-0108889

(51) Int. Cl. H01L 25/11; H01L 23/538; H01L 23/552

(52) U.S. Cl. CPC H01L 25/117; H01L 23/538; H01L 23/552; H01L 2225/1023; H01L 2225/1041

(57) ABSTRACT

A semiconductor package including an electromagnetic interference shield includes a lower interconnection structure including a lower insulating layer and a lower interconnection layer, a lower semiconductor chip disposed on the lower interconnection structure, an encapsulant on the lower interconnection structure and covering at least a portion of the lower semiconductor chip, an upper interconnection structure disposed on the encapsulant, a plurality of first through-structures disposed in the encapsulant and electrically connecting the lower interconnection structure and the upper interconnection structure, a plurality of second through-structures disposed in the encapsulant and around the lower semiconductor chip and the plurality of first through-structures, and an upper chip structure electrically connected to the upper interconnection layer, and wherein each of the plurality of second through-structures is electrically connected to one of the lower interconnection layer or the upper interconnection layer and is spaced apart from the other in a vertical direction.

### CROSS-REFERENCE TO RELATED APPLICATION(S)

This application claims priority under 35 U.S.C. § 119 to Korean Patent Application No. 10-2024-0108889, filed on Aug. 14, 2024, in the Korean Intellectual Property Office, the disclosure of which is herein incorporated by reference in its entirety.

### BACKGROUND

### 1. Technical Field

The present inventive concept relates to a semiconductor package including an EMI shield, and more particularly to a semiconductor package including a through-structure providing an EMI shielding effect.

### 2. Description of Related Art

Semiconductor devices are susceptible to external electromagnetic waves from sources like radios, cell phones, power lines, or other electronic devices. These external signals can induce unwanted noise or disturbances, leading to malfunctions or degradation in performance of semiconductor chips. Electromagnetic interference (EMI) shielding may be used in semiconductor chips to ensure their reliable operation and performance.

### SUMMARY

An aspect of the present inventive concept is to provide a semiconductor package having improved electromagnetic interference (EMI) shielding effect.

According to an aspect of the present inventive concept, a semiconductor package including an electromagnetic interference shield includes: a lower interconnection structure including a lower insulating layer and a lower interconnection layer disposed within the lower insulating layer; a lower semiconductor chip disposed on the lower interconnection structure and electrically connected to the lower interconnection layer; an encapsulant on the lower interconnection structure and covering at least a portion of the lower semiconductor chip; an upper interconnection structure disposed on the encapsulant and including an upper insulating layer and an upper interconnection layer disposed within the upper insulating layer; a plurality of first through-structures disposed in the encapsulant and electrically connecting the lower interconnection structure and the upper interconnection structure; a plurality of second through-structures disposed in the encapsulant and around the lower semiconductor chip and the plurality of first through-structures; and an upper chip structure disposed on the upper interconnection structure and electrically connected to the upper interconnection layer, wherein each of the plurality of second through-structures is electrically connected to the lower interconnection layer and is spaced apart from the upper interconnection layer in a vertical direction or is electrically connected to the upper interconnection layer and is spaced apart from the lower interconnection layer in the vertical direction.

According to an aspect of the present inventive concept, a semiconductor package includes: a lower interconnection structure including a first lower interconnection layer and a second lower interconnection layer disposed outside the first lower interconnection layer; a lower semiconductor chip on the lower interconnection structure and electrically connected to the first lower interconnection layer; an encapsulant covering at least a portion of the lower semiconductor chip on the lower interconnection structure; an upper interconnection structure disposed on the encapsulant and including a first upper interconnection layer and a second upper interconnection layer disposed outside the first upper interconnection layer; and a plurality of first and second through-structures penetrating through at least a portion of the encapsulant between the lower interconnection structure and the upper interconnection structure, wherein each of the plurality of first through-structures extends perpendicular to an upper surface of the lower interconnection structure and connects the first lower interconnection layer to the first upper interconnection layer, each of the plurality of second through-structures is in contact with the second lower interconnection layer and spaced apart from the second upper interconnection layer or is in contact with the second upper interconnection layer and spaced apart from the second lower interconnection layer, and each of the plurality of second through-structures is arranged to surround the lower semiconductor chip in a plan view, and the second lower interconnection layer or the second upper interconnection layer connected to each of the plurality of second through-structures includes a ground pattern.

According to an aspect of the present inventive concept, a semiconductor package includes: a lower interconnection structure including a lower insulating layer and a lower interconnection layer including a ground pattern; a lower semiconductor chip disposed on the lower interconnection structure; an encapsulant on the lower interconnection structure and covering the lower semiconductor chip; an upper interconnection structure disposed on the encapsulant and including an upper insulating layer and an upper interconnection layer; a plurality of first through-structures disposed around the lower semiconductor chip between the lower interconnection structure and the upper interconnection structure, defining a first region on a plane; and a plurality of second through-structures disposed around the first region between the lower interconnection structure and the upper interconnection structure and defining a second region on the plane, wherein each of the plurality of second through-structures is in contact with the ground pattern of the lower interconnection layer and is spaced apart from the upper interconnection layer by a first distance in a vertical direction, and the second through-structures adjacent to each other are spaced apart from each other by a second distance on the plane.

According to an aspect of the present inventive concept, a method of manufacturing a semiconductor package including an electromagnetic interference shield may include providing a lower interconnection structure including a lower insulating layer and a lower interconnection layer including a ground pattern, mounting a lower semiconductor chip on the lower interconnection structure, encapsulating at least a portion of the lower semiconductor chip in an encapsulant disposed on the lower interconnection structure, providing an upper interconnection structure disposed on the encapsulant and including an upper insulating layer and an upper interconnection layer, forming a plurality of first through-structures disposed around the lower semiconductor chip between the lower interconnection structure and the upper interconnection structure, and defining a first region on a plane, and forming a plurality of second through-structures disposed around the first region between the lower interconnection structure and the upper interconnection structure and defining a second region on the plane, wherein each of the plurality of second through-structures is in contact with the ground pattern of the lower interconnection layer and is spaced apart from the upper interconnection layer by a first distance in a vertical direction, and the second through-structures adjacent to each other are spaced apart from each other by a second distance on the plane.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a cross-sectional view illustrating a semiconductor package according to an embodiment of the present inventive concept;

FIG. 1B is a plan view illustrating the semiconductor package of FIG. 1A;

FIG. 2 is a plan view illustrating a semiconductor package according to an embodiment of the present inventive concept;

FIG. 3 is a cross-sectional view illustrating a semiconductor package according to an embodiment of the present inventive concept;

FIG. 4 is a cross-sectional view illustrating a semiconductor package according to an embodiment of the present inventive concept;

FIGS. 5A to 5I are cross-sectional views schematically illustrating a manufacturing process of a semiconductor package according to an embodiment of the present inventive concept; and

FIGS. 6A to 6D are cross-sectional views schematically illustrating a manufacturing process of a semiconductor package according to an embodiment of the present inventive concept.

### DETAILED DESCRIPTION

Hereinafter, embodiments of the present inventive concept are described with reference to the accompanying drawings. Embodiments are described in sufficient detail to enable those skilled in the art to practice the invention. It is to be understood that various embodiments of the invention, although different, are not necessarily mutually exclusive. For example, a certain feature, structure, or characteristic described herein in connection with an embodiment may be implemented within other embodiments without departing from the spirit and scope of the invention. In addition, it is to be understood that the location or arrangement of individual elements within each embodiment may be modified without departing from the spirit and scope of the invention. The following detailed description is, therefore, not to be taken in a limiting sense, and the scope of the present inventive concept is defined only by the appended claims, appropriately interpreted, along with the full range of equivalents to which the claims are entitled. In the drawings, like numerals refer to the same or similar elements or functionality throughout the several views. Unless otherwise specified, in this specification, terms, such as ‘top,’ ‘upper surface, ‘bottom,’ ‘lower surface, ‘side surface,’ etc. are based on the drawings and may vary depending on directions in which components are actually arranged.

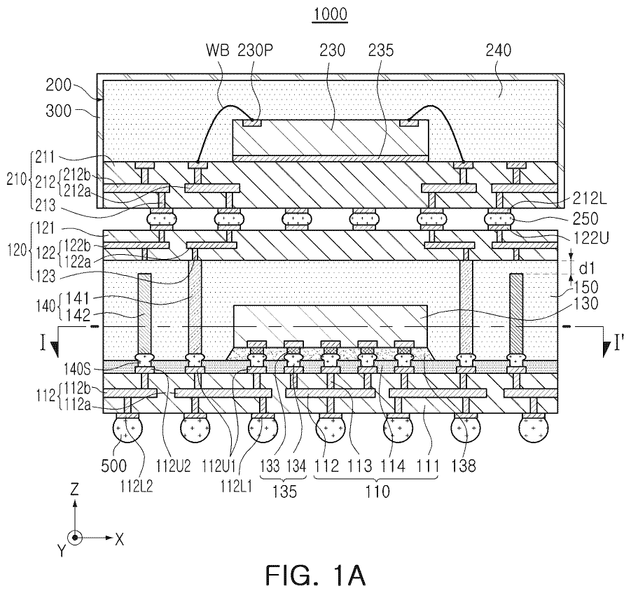

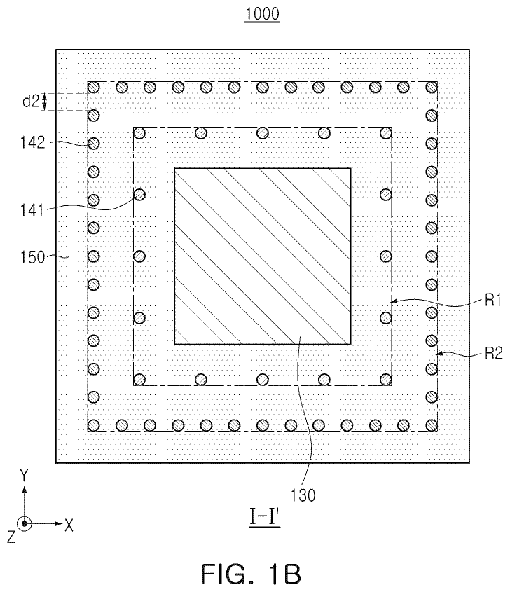

FIG. 1A is a cross-sectional view illustrating a semiconductor package 1000 according to an embodiment of the present inventive concept. FIG. 1B is a plan view illustrating a cross-section along line I-I′ of FIG. 1A.

Referring to FIG. 1A and FIG. 1B, a semiconductor package 1000 of an embodiment may include a lower interconnection structure 110, an upper interconnection structure 120, a lower semiconductor chip 130, a first through-structure 141, a second through-structure 142, an encapsulant 150, and an upper chip structure 200. Referring to FIG. 1A and FIG. 1B, the semiconductor package 1000 of an embodiment may further include a shielding layer 300 and external connection conductors 500.

The lower interconnection structure 110 may be a support substrate on which the lower semiconductor chip 130 is mounted. The lower interconnection structure 110 may include a lower insulating layer 111, a lower interconnection layer 112, and a lower interconnection via 113. The lower interconnection structure 110 may be a semiconductor package substrate including a printed circuit board (PCB), a ceramic substrate, a glass substrate, or a tape wiring board.

The lower insulating layer 111 may include, for example, a thermosetting resin, such as an epoxy resin, a thermoplastic resin, such as a polyimide, or a prepreg, an interlayer insulator (e.g., AJINOMOTO BUILD-UP FILM® (ABF)), or Flame Retardant 4 (FR-4), including an inorganic filler or/and glass fiber (glass cloth, glass fabric). The lower insulating layer 111 may include a plurality of insulating layers stacked in a vertical direction. For example, the lower insulating layer 111 may include a core layer and a build-up layer stacked on an upper surface and/or lower surface of the core layer. Depending on a process, a boundary between the plurality of lower insulating layers may not be apparent. According to an embodiment, the lower insulating layer 111 may include a photosensitive resin, such as a photoimageable dielectric (PID).

The lower interconnection layer 112 may form an electrical connection path within the lower insulating layer 111. The lower interconnection layer 112 may include, for example, at least one metal from among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C), or an alloy including two or more metals thereof. Each of the lower interconnection layers 112 may be formed of an electrolytically deposited (ED) copper foil, a rolled-annealed (RA) copper foil, ultra-thin copper foil, sputtered copper, or copper alloys. The lower interconnection layer 112 may include a plurality of pattern layers spaced apart from each other in the vertical direction. The plurality of pattern layers may extend in a horizontal direction on each vertical level. The lower interconnection layer 112 may include fewer or more pattern layers than those illustrated in the drawing. The lower interconnection layer 112 may include a first lower interconnection layer 112a and a second lower interconnection layer 112b disposed on a side of the first lower interconnection layer 112a. For example, the second lower interconnection layer 112b may be disposed at a periphery of the lower insulating layer 111. The lower interconnection layer 112 may include lower connection pads 112L1 and 112L2 and upper connection terminals 112U1 and 112U2. The lower connection pads 112L1 and 112L2 may be pad portions of a lowermost layer of the lower interconnection layer 112, and the upper connection terminals 112U1 and 112U2 may be pad portions of an uppermost layer of the lower interconnection layer 112. The lower interconnection layer 112 may perform various functions depending on a design. For example, the lower interconnection layer 112 may include a ground pattern, a power pattern, and a signal pattern, and the second lower interconnection layer 112b disposed on an outer side of the lower interconnection layer 112 may include a ground pattern.

The lower interconnection via 113 may electrically connect a plurality of lower interconnection layers 112 located on different levels within the lower insulating layer 111. The lower interconnection via 113 may electrically connect between the plurality of lower interconnection layers 112 and the lower connection pads 112L1 and 112L2, and between the plurality of lower interconnection layers 112 and the upper connection terminals 112U1 and 112U2. The lower interconnection via 113 may include, for example, at least one metal from among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C), or an alloy including two or more metals thereof. The lower interconnection via 113 may be disposed in a via hole penetrating through at least a portion of the lower insulating layer 111 and forming a conductive material conformally along a wall of the via hole. The lower interconnection via 113 may be completely fill the via hole. According to an embodiment, at least a portion of the lower interconnection via 113 may be formed in a form in which a conductive material is coated along the wall of the via hole and a space inside the via hole surrounded by the conductive material is filled with an insulating material.

The lower interconnection structure 110 may further include a protective layer 114. The protective layer 114 may be formed on an upper surface of the lower insulating layer 111. The protective layer 114 may include an opening exposing at least a portion of the upper connection terminals 112U1 and 112U2. The protective layer 114 may be formed using, for example, a solder resist. In an embodiment, a lower protective layer disposed below the lower interconnection structure 110 may be further included. The lower protective layer may include an opening exposing at least a portion of the lower connection pads 112L1 and 112L2.

The lower semiconductor chip 130 may be disposed so that an active surface on which the connection pads 130P are arranged faces the lower interconnection structure 110. The lower semiconductor chip 130 may be provided as a plurality of semiconductor chips arranged in the vertical or horizontal direction. The lower semiconductor chip 130 may be electrically connected to the first upper connection terminals 112U1 through conductive bumps 135. The conductive bumps 135 may include a pillar portion 133 and a solder portion 134. The pillar portion 133 may include copper (Cu) or an alloy of copper (Cu), and the solder portion 134 may include a low-melting-point metal, for example, tin (Sn) or an alloy (Sn—Ag—Cu) including tin (Sn). According to an embodiment, the conductive bumps 135 may include only the pillar portion 133 or only the solder portion 134. The conductive bumps 135 may be surrounded by an underfill portion 138. The underfill portion 138 may have a capillary underfill (CUF) structure, but according to an embodiment, may have a molded underfill (MUF) structure integrated with the encapsulant 150. While the lower semiconductor chip 130 is illustrated as being disposed so that an active surface on which the connection pads 130P are arranged faces the lower interconnection structure 110, embodiments are not limited thereto. For example, an additional lower semiconductor chip may be offset stacked on the lower semiconductor chip 130.

The lower semiconductor chip 130 may be a bare semiconductor chip in which no separate bump or interconnection layer is formed, but is not limited thereto. The lower semiconductor chip 130 may also be a packaged type semiconductor chip. The lower semiconductor chip 130 may include a semiconductor wafer formed of a semiconductor element, such as silicon or germanium or a compound semiconductor, such as silicon carbide (SiC), gallium arsenide (GaAs), indium arsenide (InAs), and indium phosphide (InP), or an integrated circuit (IC) formed on the semiconductor wafer.

The lower semiconductor chip 130 may be a logic chip including a central processing unit (CPU), a graphics processing unit (GPU), a field programmable gate array (FPGA), an application processor (AP), a digital signal processor, an encryption processor, a microprocessor, a microcontroller, an analog-to-digital converter, or an application-specific IC (ASIC). According to an embodiment, the lower semiconductor chip 130 may further include a memory chip including a volatile memory, such as a dynamic RAM (DRAM), or a static RAM (SRAM), and a nonvolatile memory, such as a phase change RAM (PRAM), a magnetic RAM (MRAM), a resistive RAM (RRAM), or a flash memory.

A plurality of through-structures 140 may penetrate through at least a portion of the encapsulant 150 between the lower interconnection structure 110 and the upper interconnection structure 120. The plurality of through-structures 140 may extend in a direction (e.g., in the Z-axis direction), perpendicular to an upper surface of the lower interconnection structure 110. The plurality of through-structures 140 may include a plurality of first through-structures 141 surrounding the lower semiconductor chip 130 and a plurality of second through-structures 142 surrounding the plurality of first through-structures 141.

The plurality of first through-structures 141 may penetrate through at least a portion of the encapsulant 150 on the lower interconnection structure 110. The plurality of first through-structures 141 may electrically connect the lower interconnection structure 110 to the upper interconnection structure 120. The plurality of first through-structures 141 may be arranged along the periphery of the lower semiconductor chip 130 between the lower interconnection structure 110 and the upper interconnection structure 120. The plurality of first through-structures 141 may define a first region R1 on a plane. In FIG. 1B, the first region R1 is a virtual line drawn along the structure in which the plurality of first through-structures 141 are arranged, and may have a rectangular shape, but is not limited thereto. The lower semiconductor chip 130 may be disposed within the first region R1, and the first region R1 may be understood as a signal transmission region. The upper surface of each of the plurality of first through-structures 141 may be exposed from the encapsulant 150 and may be electrically connected to a first upper interconnection layer 122a through an upper interconnection via 123. Each of the plurality of first through-structures 141 may have a cylindrical shape, but is not limited thereto, and may have a rectangular shape or a tapered shape. Each of the plurality of first through-structures 141 may have a pillar shape elongated vertically. Each of the plurality of first through-structures 141 may include copper (Cu), nickel (Ni), titanium (Ti), lead (Pb), aluminum (Al), silver (Ag), gold (Au), or platinum (Pt), or alloys thereof. In an embodiment, each of the plurality of first through-structures 141 may include copper (Cu). Each of the plurality of first through-structures 141 may be electrically connected to the first upper connection terminals 112U1 through the solder portion 140S disposed at a lower end of the first through-structure 141. The first through-structure 141 may be electrically connected to the first lower interconnection layer 112a through the first upper connection terminals 112U1. The first through-structure 141 may be electrically connected to the lower semiconductor chip 130 through the first lower interconnection layer 112a. An upper surface of the first through-structure 141 may be disposed in contact with a lower surface of the upper interconnection via 123. The first through-structure 141 may be electrically connected to the first upper interconnection layer 122a through the upper interconnection via 123.

A plurality of second through-structures 142 may penetrate through at least a portion of the encapsulant 150 on the lower interconnection structure 110. The plurality of second through-structures 142 may be electrically connected to the lower interconnection structure 110. In FIG. 1B, the plurality of second through-structures 142 may be arranged along a periphery of the first region R1 between the lower interconnection structure 110 and the upper interconnection structure 120 and may define a second region R2 on a plane. The plurality of second through-structures 142 may be arranged to surround the lower semiconductor chip 130 in a plan view. The second region R2 is a virtual line drawn along the structure in which the plurality of second through-structures 142 are arranged, and may have a rectangular shape, but is not limited thereto. The lower semiconductor chip 130 and the plurality of first through-structures 141 may be arranged in the second region R1, and the second region R2 may be an electromagnetic interference (EMI) shielding region. Each of the plurality of second through-structures 142 may be in contact with the second lower interconnection layer 112b and may be spaced apart from the second upper interconnection layer 122b in the vertical direction by a first distance d1. The second lower interconnection layer 112b electrically connected to each of the plurality of second through-structures 142 may include a ground pattern. The encapsulant 150 may have a portion extending between each of the plurality of second through-structures 142 and the second upper interconnection layer 122b. In FIG. 1A, a thickness of a portion of the encapsulant 150 overlapping each of the plurality of second through-structures 142 in the vertical direction may be equal to the first distance d1. In FIG. 1B, on a plane, the plurality of adjacent second through-structures 142 may be spaced apart from each other by a second distance d2. A cross-sectional area of the first region R1 may be less than a cross-sectional area of the second region R2, and the first region R1 may be included in the second region R2. A length of the second through-structure 142 may be less than a length of the first through-structure 141. At least one of the plurality of second through-structures 142 may be electrically connected to the second lower interconnection layer 112b including a ground pattern through a solder portion 140S disposed on the lower insulating layer 111. The second through-structure 142 may include a metal material, such as copper (Cu). Here, the first distance d1 and the second distance d2 may be the same and may be less than about 1/50 of the wavelength (λ) of an electromagnetic wave radiated from the lower semiconductor chip 130. For example, the first distance d1 and the second distance d2 may be about 0.5 mm or less or about 1 mm or less. Similarly, the first distance d1 and the second distance d2 may be the same and may be less than about 1/50 of the wavelength (λ) of a near-field signal (non-radiative) generated by the lower semiconductor chip 130. For example, the effectiveness of the plurality of second through-structures 142 as an EMI shield may be directly related to the first distance d1 and the second distance d2 compared to the wavelength (λ) of the EMI signal. If the first distance d1 and the second distance d2 are smaller than λ, e.g., less than about 1/50 of the wavelength (λ), the plurality of second through-structures 142 may block the EMI. Herein, the first distance d1 may be referred to as openings of the second through-structure 142 and the second distance d2 may be referred to as apertures between the second through-structure 142.

According to an embodiment, the semiconductor package 1000 having improved shielding effect for EMI radiated from or generated by the lower semiconductor chip 130 by introducing the second through-structure 142 structure disposed along the periphery of the lower semiconductor chip 130 and disposed on the outer region of the lower interconnection structure 110 may be provided.

The encapsulant 150 may encapsulate at least a portion of each of the lower semiconductor chip 130, the first through-structure 141, and the second through-structure 142, respectively, on the upper surface of the lower interconnection structure 110. The encapsulant 150 may cover a side surface of each of the lower semiconductor chip 130 and the plurality of first and second through-structures 141 and 142 and may cover an upper surface of each of the plurality of second through-structures 142. The encapsulant 150 may cover an upper surface of the lower semiconductor chip 130. The encapsulant 150 may expose the upper surface of the lower semiconductor chip 130 and an upper surface of the encapsulant 150 and the upper surface of the lower semiconductor chip 130 may be coplanar. The encapsulant 150 may include, for example, a thermosetting resin, such as an epoxy resin, a thermoplastic resin, such as a polyimide, a prepreg, ABF, FR-4, BT, or epoxy molding compound (EMC) obtained by impregnating an inorganic filler with the resins.

The upper interconnection structure 120 may be disposed on the encapsulant 150. The upper interconnection structure 120 may be a structure electrically connecting the lower interconnection structure 110 and the lower semiconductor chip 130 to the upper chip structure 200. The upper interconnection structure 120 may include an upper insulating layer 121, an upper interconnection layer 122 arranged within the upper insulating layer 121, and an upper interconnection via 123 connecting the upper interconnection layers 122 arranged on different levels. The upper interconnection layer 122 may include a first upper interconnection layer 122a disposed adjacent to the center of the upper interconnection structure 120 and a second upper interconnection layer 122b disposed at a periphery of the upper insulating layer 121 and on the outside of the first upper interconnection layer 122a. The first upper interconnection layer 122a may be electrically connected to the first lower interconnection layer 112a through a plurality of first through-structures 141. Pads may be disposed between the first lower interconnection layer 112a through a plurality of first through-structures 141. The upper interconnection layer 122 may include a ground pattern, a power pattern, and a signal pattern. The second upper interconnection layer 122b disposed at the periphery of the upper insulating layer 121 and on the outside of the upper interconnection layer 122, among the upper interconnection layers 122, may include a ground pattern. Since the upper interconnection structure 120 has the same or similar characteristics as the lower interconnection structure 110, the other descriptions related to the upper interconnection structure 120 may be disposed similar to the lower interconnection structure 110.

The upper chip structure 200 may be disposed on the upper interconnection structure 120 and may include an interconnection member 210, an upper semiconductor chip 230, and an upper encapsulant 240.

The interconnection member 210 may include an insulating member 211 and interconnection patterns 212. The insulating member 211 may include a thermosetting resin, such as an epoxy resin, a thermoplastic resin, such as a polyimide, or a prepreg, ABF, FR-4, or BT obtained by impregnating an inorganic filler with the resins, or a photosensitive resin, such as PID. The interconnection patterns 212 may include a metal material including, for example, copper (Cu), aluminum (Al), silver (Ag), tin (Sn), gold (Au), nickel (Ni), lead (Pb), or titanium (Ti), or alloys thereof. The interconnection member 210 may be electrically connected to the upper interconnection structure 120 through intermediate connection bumps 250. For example, the interconnection member 210 may be electrically connected to the upper interconnection structure 120 through lower connection pads 212L disposed on a lower surface of the interconnection member 210, the intermediate connection bumps 250, and upper connection pads 122U on an upper surface of the upper interconnection structure 120.

The upper semiconductor chip 230 may be mounted on the interconnection member 210 by wire bonding or flip-chip bonding. For example, the upper semiconductor chip 230 may be disposed on an upper surface of the interconnection member 210 by an adhesive layer 235 and may be electrically connected to the interconnection patterns 212 through the upper pad of the interconnection member 210 by a bonding wire (WB). In an example, the upper semiconductor chip 230 may correspond to a chip of the same type as the lower semiconductor chip 130, but is not limited thereto. While the upper semiconductor chip 230 is illustrated as being wire bonded to the interconnection member 210, embodiments are not limited thereto. For example, multiple upper semiconductor chips may be disposed on the interconnection member 210.

The upper encapsulant 240 may encapsulate at least a portion of the upper semiconductor chip 230 on the interconnection member 210. The upper encapsulant 240 may include a material the same as or similar to the encapsulant 150.

The shielding layer 300 may be disposed to conformally cover an outer surface of the upper chip structure 200. The shielding layer 300 may have a uniform thickness along a perimeter of the upper chip structure 200, but is not limited thereto. The shielding layer 300 may be formed to cover a side surface of the insulating member 211 and the upper encapsulant 240 of the upper chip structure 200, may be in contact with at least a portion of the second interconnection patterns 212b arranged at a periphery of the insulating member 211 and on the outer side among the interconnection patterns 212, and may be electrically connected to the second interconnection patterns 212b. The second interconnection patterns 212b may include a ground pattern and may be in contact with the shielding layer 300. For example, the second interconnection patterns 212b may include a ground pattern and may be in contact with an internal surface of the shielding layer 300.

The shielding layer 300 may include a conductive material for EMI shielding, for example, iron (Fe), nickel (Ni), gold (Au), silver (Ag), copper (Cu), or aluminum (Al), or alloys thereof. The shielding layer 300 may include at least one layer of a conductive thin film. For example, the shielding layer 300 may be a three-layer thin film in which a stainless steel (SUS) film, a copper (Cu) film, and a stainless steel (SUS) film may be sequentially stacked.

External connection conductors 500 may be disposed on a lower surface of the lower interconnection structure 110. The external connection conductors 500 may be electrically connected to the semiconductor chip 130 and the first through-structure 141 through the lower interconnection layer 112. The semiconductor package 1000 may be connected to an external device, such as a module substrate or a system board through the external connection conductors 500. For example, the external connection conductors 500 may include for example, tin (Sn) or a tin-silver-copper (Sn—Ag—Cu) alloy or a tin-aluminum-copper (Sn—Al—Cu) alloy including tin (Sn). The external connection conductors 500 may include a low-melting-point metal. According to an embodiment, the external connection conductors 500 may have a shape in which a pillar (or underbump metal) and a ball are combined. The pillar may include copper (Cu) or an alloy of copper (Cu), and the ball may include a solder ball. According to an embodiment, the lower insulating layer 111 may include a resist layer, which may protect the external connection conductors 500 from external physical and chemical damage.

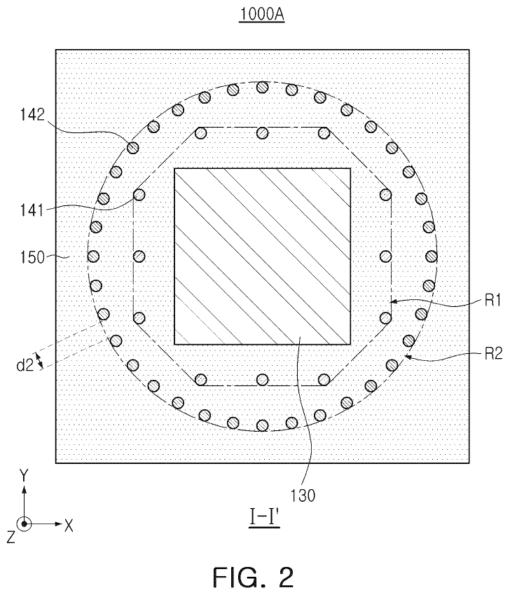

FIG. 2 is a plan view illustrating a semiconductor package 1000A according to an embodiment of the present inventive concept.

Referring to FIG. 2, the semiconductor package 1000A of an embodiment may have the same or similar features as those described with reference to FIG. 1A and FIG. 1B. Referring to FIG. 2, the shape in which the plurality of second through-structures 142 are arranged is circular. The second region R2 may be defined by the plurality of second through-structures 142. In the semiconductor package 1000A according to an embodiment, the first region R1 may have an octagonal shape and the second region R2 may have a circular shape, but are not limited thereto. The lower semiconductor chip 130 may be disposed within the second region R2 and may be included within the first region R1 defined by the first through-structures 141. The first through-structures 141 electrically connecting the lower interconnection structure 110 and the upper interconnection structure 120 may be disposed along the periphery of the lower semiconductor chip 130. Depending on the number or arrangement of the lower semiconductor chips 130 disposed within the first region R1 and the arrangement of the plurality of first through-structures 141 surrounding the lower semiconductor chip 130, the structure in which the plurality of second through-structures 142 are arranged and the shape of the second region R2 defined by the structure may be freely changed.

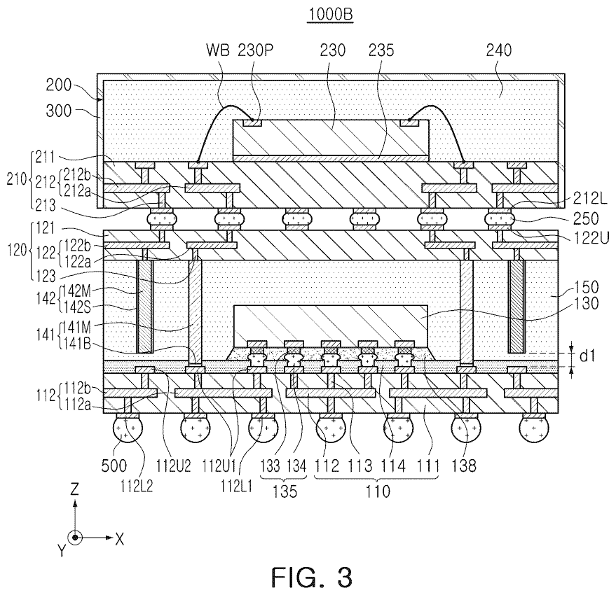

FIG. 3 is a cross-sectional view illustrating a semiconductor package 1000B according to an embodiment of the present inventive concept.

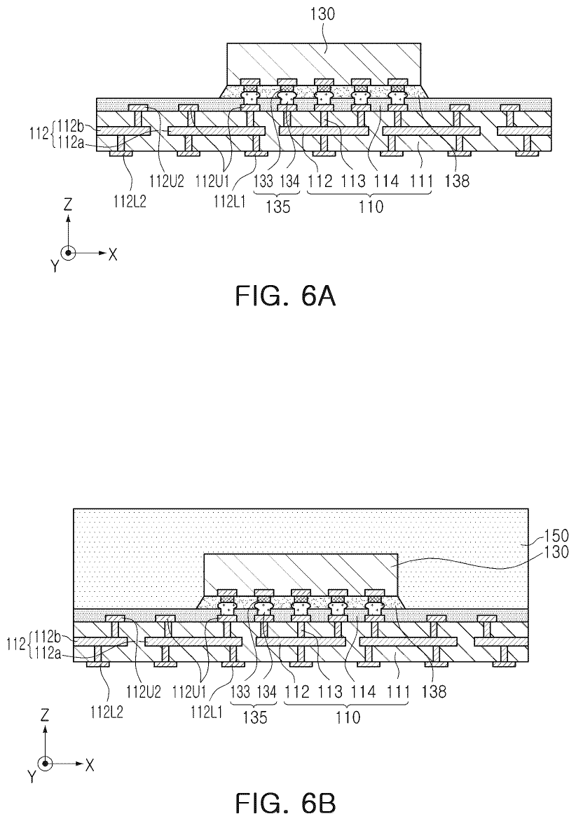

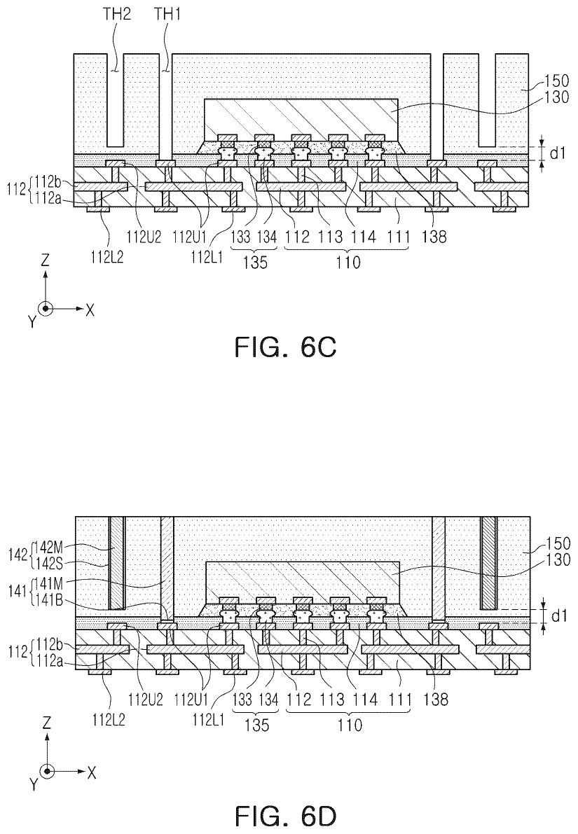

Referring to FIG. 3, the semiconductor package 1000B of an embodiment may have the same or similar features as those described with reference to FIG. 1A, FIG. 1B, and FIG. 2, except that the first through-structure 141 includes a barrier layer 141B and a conductive electrode 141M, the second through-structure 142 includes a conductive layer 142M and an insulating spacer layer 142S, and the second through-structure 142 is spaced apart from the second lower interconnection layer 112b in the vertical direction. The first through-structure 141 may include the barrier layer 141B disposed in a lower portion and the conductive electrode 141M disposed on the barrier layer 141B. The barrier layer 141B may correspond to a portion of a seed layer in a plating process for forming the conductive electrode 141M. The second through-structure 142 may include the conductive layer 142M and the insulating spacer layer 142S surrounding a side surface of the conductive layer 142M. A thickness of the insulating spacer layer 142S may be the same in all regions, but is not limited thereto. The insulating spacer layer 142S may include the same material as that of the encapsulant 150, but is not limited thereto. The second through-structure 142 may be electrically connected to the second upper interconnection layer 122b and may be disposed to be spaced apart from the second lower interconnection layer 122a in the vertical direction. The second upper interconnection layer 122b electrically connected to each of the plurality of second through-structures 142 may include a ground pattern. A lower surface of the second through-structure 142 may be spaced apart from the upper surface of the second upper connection terminal 112U2 by the first distance d1. The first through-structure 141 and the second through-structure 142 in FIG. 3 may be formed by a different process from the first through-structure 141 and the second through-structure 142 in FIG. 1A and FIG. 1B. For example, the first through-structure 141 and the second through-structure 142 in FIG. 3 may be formed by a process will be described with reference to FIG. 6A and subsequent drawings.

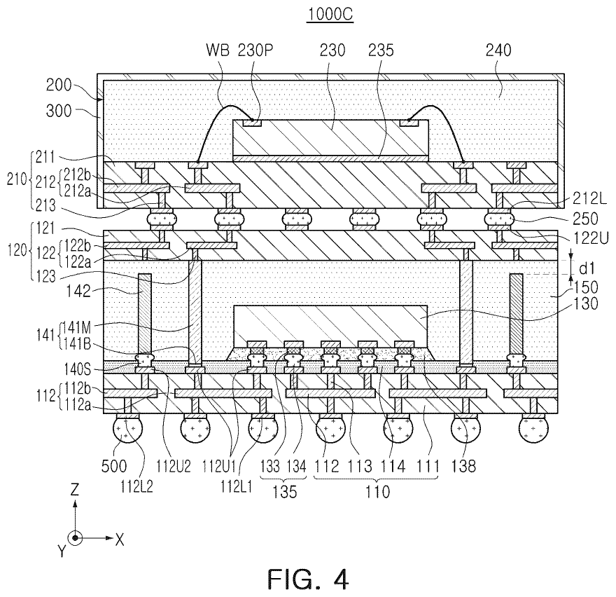

FIG. 4 is a cross-sectional view illustrating a semiconductor package 1000C according to an embodiment of the present inventive concept.

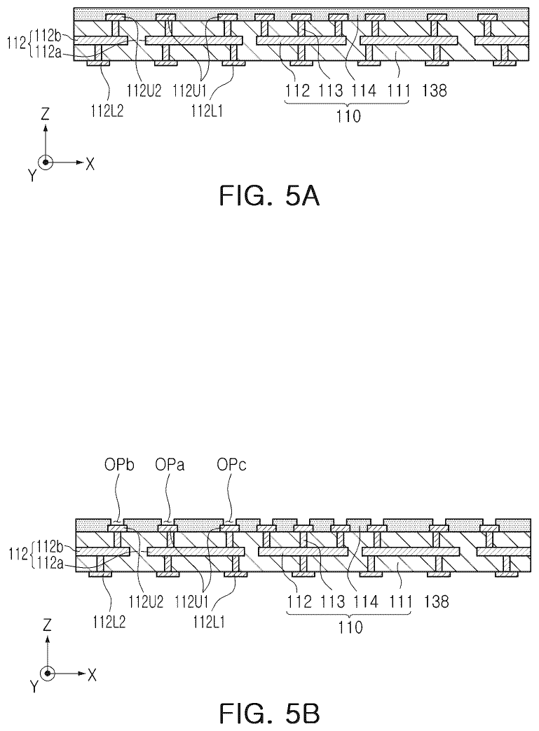

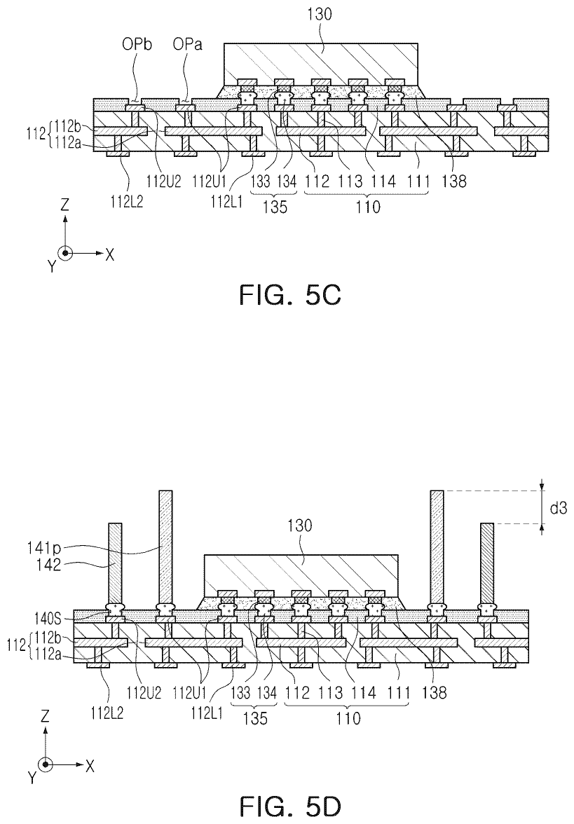

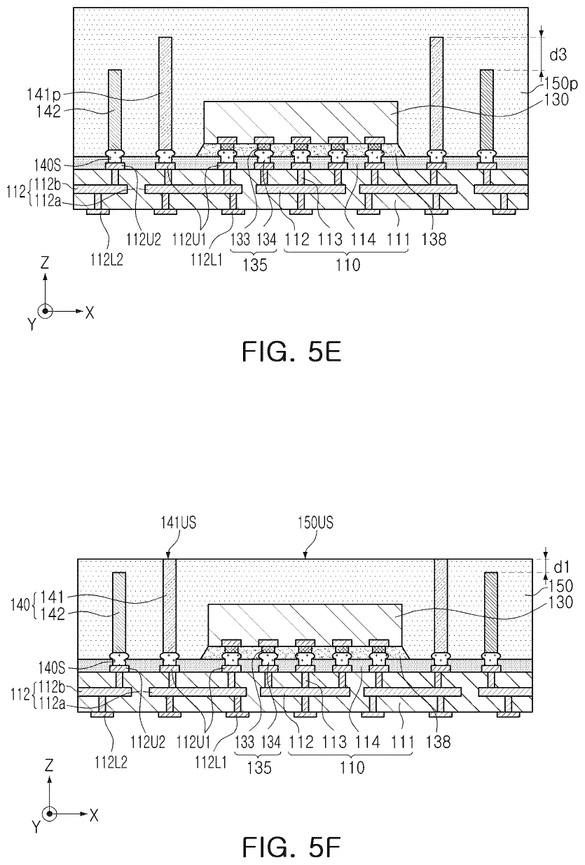

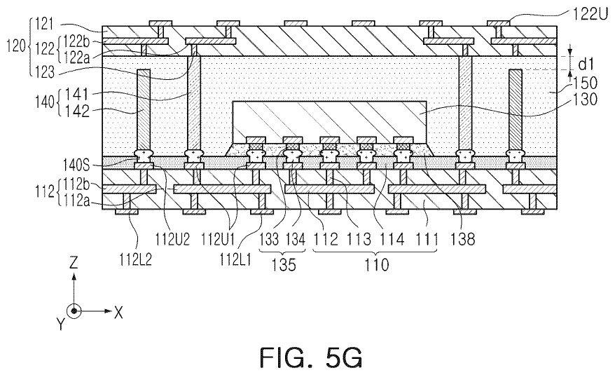

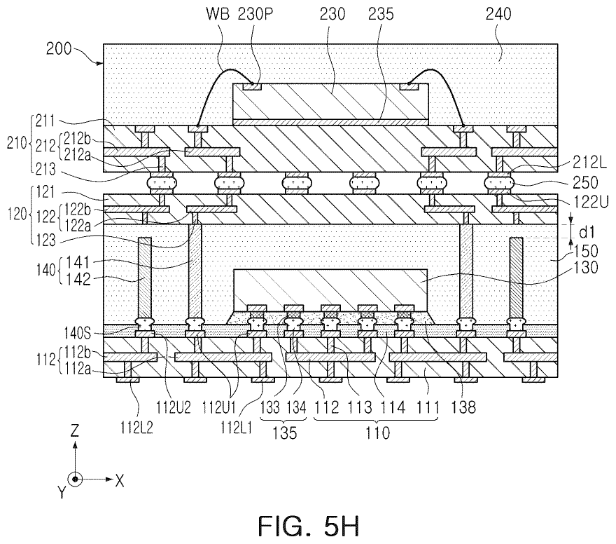

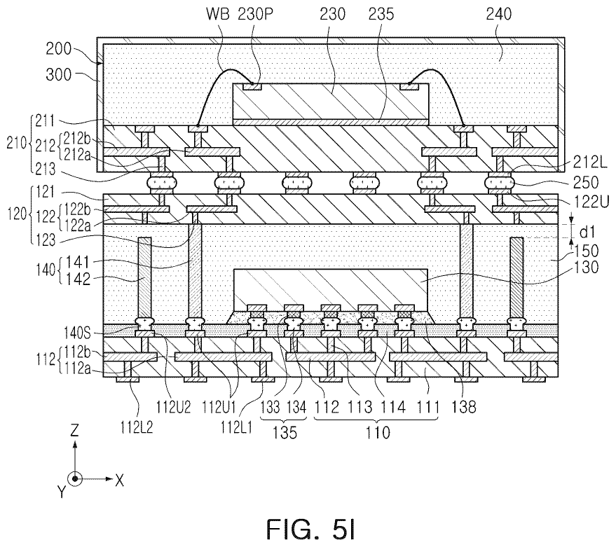

Referring to FIG. 4, the semiconductor package 1000C of an embodiment may have the same or similar features as those described with reference to FIG. 1A, FIG. 1B, FIG. 2, and FIG. 3, except that the first through-structure 141 includes the barrier layer 141B and the conductive electrode 141M and the second through-structure 142 is connected to the second lower interconnection layer 112b through the solder portion 140S. The semiconductor package 1000C according to an embodiment may be understood as having a combination of the features of the second through-structure 142 of the semiconductor package (1000, see FIG. 1A) and the features of the first through-structure 141 of the semiconductor package (1000B, see FIG. 3) and may be formed by combining the manufacturing processes of FIGS. 5A to 5I and FIGS. 6A to 6D, described herein. In addition, the semiconductor package 1000C according to an embodiment is not limited thereto and may be understood as including an embodiment in which the features of the first through-structure 141 of the semiconductor package (1000, see FIG. 1A) and the features of the second through-structure 142 of the semiconductor package (1000B, see FIG. 3) are combined.

FIGS. 5A to 5I are cross-sectional views schematically illustrating a manufacturing process of the semiconductor package 1000 according to an embodiment of the present inventive concept.

Referring to FIG. 5A, the lower interconnection structure 110 may be prepared. The lower interconnection structure 110 may include the lower insulating layer 111, the lower interconnection layer 112 arranged within the lower insulating layer 111, the lower interconnection via 113 connecting the lower interconnection layers 112 arranged on different levels, and the protective layer 114 disposed on the upper surface of the lower insulating layer 111. The protective layer 114 may cover the upper connection terminals 112U1 and 112U2.

Referring to FIG. 5B, openings OPa, OPb, and OPc may be formed in the protective layer 114 to expose at least a portion of the upper connection terminals 112U1 and 112U2 from the protective layer 114. The openings OPa, OPb, and OPc may be formed by a process of etching a portion of the protective layer 114. The openings OPa, OPb, and OPc may expose at least a portion of the upper connection terminals 112U1 and 112U2, and may be narrower than a width of the upper connection terminals 112U1 and 112U2 in a first direction (e.g., in an X-axis direction) as illustrated in FIG. 5B, but are not limited thereto. In an embodiment, openings OPa, OPb, and OPc may be omitted, and the upper connection terminals 112U1 and 112U2 ay be exposed by a process of grinding a portion of the protective layer 114. In an embodiment, a width of the openings OPa, OPb, and OPc in the first direction may be wider than a width of the upper connection terminals 112U1 and 112U2 in the first direction, and at least a portion of an upper surface of the lower insulating layer 111 may be exposed from the protective layer 114. Openings OPc adjacent to the center of the lower interconnection structure 110 may provide a region for mounting a lower semiconductor chip 130, and openings OPa and OPb adjacent to the outer portion of the lower interconnection structure 110 may provide regions for arranging the first through-structure 141 and the second through-structure 142, respectively.

Referring to FIG. 5C, the lower semiconductor chip 130 may be mounted on the lower interconnection structure 110. The lower semiconductor chip 130 may be electrically connected to first upper connection terminals 112U1 through conductive bumps 135. The first upper connection terminals 112U1 are upper connection terminals adjacent to the center among the upper connection terminals 112U1 and 112U2 and may be electrically connected to the first lower interconnection layer 112a among the lower interconnection layer 112 through the lower interconnection via 113. The conductive bumps 135 may include the pillar portion 133 and the solder portion 134, and the solder portion 134 may fill the openings OPc and may be in contact with at least a portion of the protective layer 114. The underfill portion 138 may be formed to surround the conductive bumps 135 between the protective layer 114 and the lower semiconductor chip 130 and may be formed through a thermal curing process. According to an embodiment, the underfill portion 138 may have a molded underfill (MUF) structure integrated with the encapsulant 150 and may be formed in a process of forming the encapsulant 150 (see FIG. 5E).

Referring to FIG. 5D, preliminary first through-structures 141p and the second through-structures 142 may be arranged on the lower interconnection structure 110. The preliminary first through-structures 141p and the second through-structures 142 may include a metal material, and in an embodiment, may include copper (Cu), but are not limited thereto. The preliminary first through-structures 141p and the second through-structures 142 may be connected to the lower interconnection structure 110 through solder portions 140S arranged at the respective lower ends. Specifically, the solder portions 140S may be disposed in the openings OPa and OPb located at the outer side of the lower interconnection structure 110, and the preliminary first through-structures 141p and the second through-structures 142 may be connected to the first upper connection terminals 112U1 and the second upper connection terminals 112U2, respectively, through the solder portions 140S. In an embodiment in which the openings OPa, OPb, and OPc are omitted, and the preliminary first through-structures 141p and the second through-structures 142 may be disposed on the first upper connection terminals 112U1 and the second upper connection terminals 112U2, and the solder portions 140S may be omitted. A length of each of the preliminary first through-structures 141p in the vertical direction (e.g., in the Z-axis direction) may be greater than a length of each of the second through-structures 142 in the vertical direction, and a difference between the length of each of the preliminary first through-structures 141p in the vertical direction (e.g., in the Z-axis direction) and the length of each of the second through-structures 142 in the vertical direction may be referred to as a third distance d3. In this case, the third distance d3 may be greater than the first distance d1 (see FIG. 1A).

Referring to FIG. 5E, a preliminary encapsulating layer 150p covering the lower semiconductor chip 130, the preliminary first through-structures 141p, and the second through-structures 142 may be formed on the lower interconnection structure 110. On the lower interconnection structure 110, after applying an encapsulating material to encapsulate the lower semiconductor chip 130, the preliminary first through-structures 141p, and the second through-structures 142, the encapsulating material may be cured to form the preliminary encapsulating layer 150p. The preliminary encapsulating layer 150p may be formed to cover an upper surface of each of the preliminary first through-structures 141p and the second through-structures 142. The preliminary encapsulating layer 150p may be formed to have a thickness greater than the length of each of the preliminary first through-structures 141p and the second through-structures 142 in the vertical direction. The preliminary encapsulating layer 150p may be formed, for example, by applying and curing epoxy molding compound (EMC).

Referring to FIG. 5F, a portion of an upper region of the preliminary encapsulating layer 150p may be planarized to form the encapsulant 150. The upper portion of the preliminary encapsulating layer (150p, see FIG. 5E) may be planarized by a polishing device. The planarizing process may include a grinding process or a chemical mechanical polishing (CMP) process. By the planarizing process, at least a portion of the preliminary first through-structures 141p may be removed, and the first through-structures 141 may be formed. By the planarizing process, the upper surface 141US of each of the first through-structures 141 may be exposed from the upper surface 150US of the encapsulant 150. The upper surface 150US of the encapsulant 150 and the upper surfaces 141US of the first through-structures 141 may be coplanar. Accordingly, a flat surface formed by the upper surface 150US of the encapsulant 150 and the upper surface 141US of the first through-structures 141 may be formed, but is not limited thereto. The length of each of the first through-structures 141 in the vertical direction (e.g., in the Z-axis direction) may be greater than the length of each of the second through-structures 142 in the vertical direction. The difference between the length of each of the first through-structures 141 in the vertical direction (e.g., in the Z-axis direction) and the length of each of the second through-structures 142 in the vertical direction may be referred to as the first distance d1. In this case, the first distance d1 may be less than the third distance (d3, see FIG. 5D). The distance from the upper surface 150US of the encapsulant 150 to the upper surface of each of the plurality of second through-structures 142 in the vertical direction (e.g., in the Z-axis direction) may be referred to as the first distance d1.

Referring to FIG. 5G, the upper interconnection structure 120 may be disposed on the encapsulant 150. A lower surface of the upper interconnection structure 120 may be located on the same plane as the upper surface of the encapsulant 150. The upper insulating layer 121 may be in contact with at least a portion of the upper surface of the encapsulant 150. Each of the first through-structures 141 may be electrically connected to the first upper interconnection layer 122a disposed in a region adjacent to the center of the upper interconnection structure 120 through the upper interconnection vias 123. The upper connection pads 122U may be formed on or in the upper insulating layer 121 or the upper interconnection structure 120.

Referring to FIG. 5H, the upper chip structure 200 may be disposed on the upper interconnection structure 120. The upper chip structure 200 may correspond to a package structure including the interconnection member 210, the upper semiconductor chip 230 mounted on the interconnection member 210, and the upper encapsulant 240 covering the upper semiconductor chip 230 on the interconnection member 210. The upper chip structure 200 may include the lower connection pads 212L arranged on the lower surface of the insulating member 211 and may be electrically connected to the upper connection pads 122U of the upper interconnection structure 120 through intermediate connection bumps 250 arranged below each of the lower connection pads 212L. The lower connection pads 212L may be formed on or in the insulating member 211 of the interconnection member 210. In an embodiment, an underfill portion may be added between the interconnection member 210 and the upper interconnection structure 120, and to surround the intermediate connection bumps 250.

Referring to FIG. 5I, the shielding layer 300 covering the outer surface of the upper chip structure 200 may be formed. The shielding layer 300 may conformally cover the outer surface of the upper chip structure 200, but is not limited thereto. The shielding layer 300 may be formed by a method, such as spraying a metal material toward the outer surface of the upper chip structure 200. The shielding layer 300 may be formed to cover the side surface of the insulating member 211 and the upper encapsulant 240 of the upper chip structure 200, may be in contact with at least a portion of the second interconnection patterns 212b arranged on the outer side among the interconnection patterns 212, and may be electrically connected to the second interconnection patterns 212b. The second interconnection patterns 212b may include a ground pattern and may be in contact with an internal surface of the shielding layer 300. The shielding layer 300 may perform a function of shielding electromagnetic waves radiated from or generated by the upper semiconductor chip 230.

Referring to FIG. 1A and FIG. 1B, the semiconductor package 1000 according to an embodiment may be formed by forming the external connection conductors 500 below the lower interconnection structure 110. The external connection conductors 500 may be attached to the lower connection pads 112L1 and 112L2.

FIGS. 6A to 6D are cross-sectional views schematically illustrating a manufacturing process of the semiconductor package 1000B according to an embodiment of the present inventive concept.

Referring to FIG. 6A, first, the lower semiconductor chip 130 may be mounted on the lower interconnection structure 110. A process of mounting the lower semiconductor chip 130 may be performed without performing a process of etching the protective layer 114 disposed on an outer side of the lower interconnection structure 110 to expose some of the upper connection terminals 112U1 and 112U2. The lower semiconductor chip 130 may be connected to some of the first upper connection terminals 112U1 through conductive bumps 135 and may be electrically connected to the first lower interconnection layer 112a through the first upper connection terminals 112U1.

Referring to FIG. 6B, the encapsulant 150 encapsulating the lower semiconductor chip 130 may be formed on the lower interconnection structure 110. After applying the encapsulating material encapsulating the lower semiconductor chip 130 on the lower interconnection structure 110, the encapsulating material may be cured to form the encapsulant 150. The encapsulant 150 may be formed, for example, by applying and curing EMC.

Referring to FIG. 6C, a first through-hole TH1 and a second through-hole TH2 penetrating through at least a portion of the encapsulant 150 may be formed. Each of the first through-hole TH1 and the second through-hole TH2 may be formed by removing a portion of the encapsulant 150 overlapping at least a portion of the upper connection terminals 112U1 and 112U2 in a direction, perpendicular to the upper surface of the encapsulant 150. The first through-hole TH1 and the second through-hole TH2 may be formed by using a physical process, such as a laser. At least a portion of the first upper connection terminal 112U1 may be exposed from the encapsulant 150 and the protective layer 114 by the first through-hole TH1. A distance from the upper surface of the encapsulant 150 exposed by the second through-hole TH2 to the second upper connection terminal 112U2 covered by the protective layer 114 may be referred to as the first distance d1.

Referring to FIG. 6D, the first and second through-structures 141 and 142 may be formed in the first and second through-holes TH1 and TH2, respectively.

The first through-structure 141 may be formed through a plating process. The first through-structure 141 may include the barrier layer 141B disposed on the first upper connection terminal 112U1 of the lower interconnection structure 110 and the conductive electrode 141M disposed on the barrier layer 141B. The barrier layer 141B may correspond to a portion of a seed layer for the plating process.

The second through-structure 142 may be formed through a process of inserting the conductive layer 142M including copper (Cu) into the second through-hole (TH2, see FIG. 6C). The conductive layer 142M may include copper and may have a cylindrical shape, but is not limited thereto. A cross-sectional area of the conductive layer 142M on a plane may be smaller than a cross-sectional area of the second through-hole TH2 on a plane. After the conductive layer 142M is disposed in the second through-hole TH2, a remaining empty space may be filled with an insulating material to form the insulating spacer layer 142S. The insulating spacer layer 142S may separate the conductive layer 142M from the encapsulant 150. The insulating spacer layer 142S may include an insulating material, and in an embodiment, may include the same material as that of the encapsulant (e.g., EMC), but is not limited thereto. A lower surface of the conductive layer 142M may be in contact with the encapsulant 150, and a distance from a lower surface of the conductive layer 142M to an upper surface of the second upper connection terminal 112U2 may be referred to as the first distance d1.

Referring to FIGS. 5D to 5F and FIGS. 6B to 6D, the first and second through-structures 141 and 142 may be formed by different processes. For example, the first through-structures 141 may be formed as in a process of FIGS. 5D to 5F, and the second through-structures 142 may be subsequently formed as in a process of FIGS. 6B to 6D.

Referring to FIG. 3, in a subsequent process, a process as described with reference to FIGS. 5G to 5I may be performed in the same or similar manner, and the external connection conductors 500 may be formed below the lower interconnection structure 110, thereby forming the semiconductor package 1000B according to an embodiment. The external connection conductors 500 may be attached to the lower connection pads 112L1 and 112L2.

According to embodiments of the present inventive concept, by introducing a metal structure disposed along the periphery of the lower semiconductor chip, the semiconductor package having improved EMI shielding effect may be provided. For example, the metal structure disposed along the periphery of the lower semiconductor chip, the semiconductor package having improved EMI shielding effect may be an EMI shield according to an embodiment.

According to an embodiment of the present inventive concept and referring to FIGS. 5A to 5I and FIGS. 6A to 6D, a method of manufacturing a semiconductor package 100 including an electromagnetic interference shield may include providing a lower interconnection structure 110 including a lower insulating layer 111 and a lower interconnection layer 112 including a ground pattern (e.g., see FIGS. 5A to 5B and FIG. 6A), mounting a lower semiconductor chip 130 on the lower interconnection structure 110 (e.g., see FIG. 5C and FIG. 6A), encapsulating at least a portion of the lower semiconductor chip 130 in an encapsulant 150 disposed on the lower interconnection structure 110 (e.g., see FIG. 5E and FIG. 6B), providing an upper interconnection structure 120 disposed on the encapsulant 150 and including an upper insulating layer 121 and an upper interconnection layer 122 (e.g., see FIG. 5G), forming a plurality of first through-structures 141 disposed around the lower semiconductor chip 130 between the lower interconnection structure 110 and the upper interconnection structure 120, and defining a first region R1 on a plane (see FIG. 1B), and forming a plurality of second through-structures 142 disposed around the first region R1 between the lower interconnection structure 110 and the upper interconnection structure 120 and defining a second region R2 on the plane (see FIG. 1B), wherein each of the plurality of second through-structures 142 may be in contact with the ground pattern of the lower interconnection structure 110 and may be spaced apart from the upper interconnection structure 120 by a first distance d1 in a vertical direction, and the second through-structures 142 adjacent to each other may be spaced apart from each other by a second distance d2 on the plane. In an embodiment, each of the plurality of second through-structures 142 may be in contact with a ground pattern of the upper interconnection structure 120 and may be spaced apart from the lower interconnection structure 110 by a first distance d1 in a vertical direction.

In an embodiment and referring to FIG. 5D and FIG. 5E, the plurality of first through-structures 141 and the plurality of second through-structures 142 may be formed on the lower interconnection structure 110 and the encapsulating encapsulates the portion of the lower semiconductor chip 130 and the plurality of first through-structures 141 and the plurality of second through-structures 142 in the encapsulant 150.

In an embodiment and referring to FIG. 6C and FIG. 6D, first and second through-holes TH1 and TH2 may be formed in the encapsulant 150 and the plurality of first through-structures 141 and the plurality of second through-structures 142 may be formed in the first and second through-holes TH1 and TH2, respectively.

While embodiments have been illustrated and described herein, it will be apparent to those skilled in the art that modifications and variations could be made without departing from the scope of the present inventive concept as defined by the appended claims.

What is claimed is:

1. A semiconductor package including an electromagnetic interference shield comprising:
a lower interconnection structure including a lower insulating layer and a lower interconnection layer within the lower insulating layer;
a lower semiconductor chip on the lower interconnection structure and electrically connected to the lower interconnection layer;
an encapsulant on the lower interconnection structure and covering at least a portion of the lower semiconductor chip;
an upper interconnection structure disposed on the encapsulant and including an upper insulating layer and an upper interconnection layer disposed within the upper insulating layer;
a plurality of first through-structures disposed in the encapsulant and electrically connecting the lower interconnection structure and the upper interconnection structure;
a plurality of second through-structures disposed in the encapsulant and around the lower semiconductor chip and the plurality of first through-structures; and
an upper chip structure disposed on the upper interconnection structure and the upper chip structure electrically connected to the upper interconnection layer,
wherein each of the plurality of second through-structures is electrically connected to the lower interconnection layer and is spaced apart from the upper interconnection layer in a vertical direction or is electrically connected to the upper interconnection layer and is spaced apart from the lower interconnection layer in the vertical direction.

2. The semiconductor package of claim 1, wherein the upper interconnection layer includes a first upper interconnection layer and a second upper interconnection layer disposed at a periphery of the upper interconnection layer and on an outside of the first upper interconnection layer, each of the plurality of first through-structures is in contact with the first upper interconnection layer, and each of the plurality of second through-structures is spaced apart from the second upper interconnection layer in the vertical direction.

3. The semiconductor package of claim 2, wherein the encapsulant has a portion extending between the plurality of second through-structures and the second upper interconnection layer, respectively.

4. The semiconductor package of claim 2, wherein the first upper interconnection layer comprises:
a plurality of first upper interconnection layers arranged on different levels, and
a plurality of upper interconnection vias electrically connected to the plurality of first upper interconnection layers with the upper interconnection vias.

5. The semiconductor package of claim 2, further comprising a shielding layer conformally covering an outer surface of the upper chip structure.

6. The semiconductor package of claim 5, wherein
the upper chip structure includes an insulating member and interconnection patterns arranged within the insulating member, and
at least a portion of the interconnection patterns is in contact with an internal surface of the shielding layer.

7. The semiconductor package of claim 1, wherein the lower interconnection layer includes a first lower interconnection layer and a second lower interconnection layer disposed on an outside of the first lower interconnection layer, each of the plurality of first through-structures is in contact with the first lower interconnection layer, and each of the plurality of second through-structures is spaced apart from the second lower interconnection layer in the vertical direction.

8. The semiconductor package of claim 7, wherein the encapsulant has a portion extending between the plurality of second through-structures and the second lower interconnection layer, respectively.

9. The semiconductor package of claim 1, further comprising:
conductive bumps disposed between the lower interconnection structure and the lower semiconductor chip;
an underfill portion covering at least a portion of each of the conductive bumps; and
external connection conductors arranged below the lower interconnection structure and electrically connected to the lower interconnection layer.

10. The semiconductor package of claim 1, wherein at least one of the lower interconnection layer and the upper interconnection layer includes a ground pattern, and
the plurality of second through-structures include at least one through-structure connected to the ground pattern of the lower interconnection layer or the upper interconnection layer.

11. A semiconductor package comprising:
a lower interconnection structure including a first lower interconnection layer and a second lower interconnection layer disposed outside the first lower interconnection layer;
a lower semiconductor chip on the lower interconnection structure and electrically connected to the first lower interconnection layer;
an encapsulant covering at least a portion of the lower semiconductor chip on the lower interconnection structure;
an upper interconnection structure disposed on the encapsulant and including a first upper interconnection layer and a second upper interconnection layer disposed outside the first upper interconnection layer; and
a plurality of first and second through-structures penetrating through at least a portion of the encapsulant between the lower interconnection structure and the upper interconnection structure,
wherein each of the plurality of first through-structures extends perpendicular to an upper surface of the lower interconnection structure, each of the plurality of first through-structures connects the first lower interconnection layer to the first upper interconnection layer, each of the plurality of second through-structures is in contact with the second lower interconnection layer and spaced apart from the second upper interconnection layer or is in contact with the second upper interconnection layer and spaced apart from the second lower interconnection layer, and each of the plurality of second through-structures is arranged to surround the lower semiconductor chip in a plan view, and the second lower interconnection layer or the second upper interconnection layer connected to each of the plurality of second through-structures includes a ground pattern.

12. The semiconductor package of claim 11, wherein a length of each of the plurality of second through-structures is less than a length of each of the plurality of first through-structures.

13. The semiconductor package of claim 11, wherein each of the plurality of second through-structures extends perpendicular to the upper surface of the lower interconnection structure and includes a conductive layer and an insulating spacer layer surrounding a side surface of the conductive layer.

14. The semiconductor package of claim 13, wherein the conductive layer is in contact with the encapsulant.

15. The semiconductor package of claim 13, wherein the insulating spacer layer includes the same material as that of the encapsulant.

16. The semiconductor package of claim 13, wherein the conductive layer includes copper (Cu).

17. The semiconductor package of claim 11, wherein each of the plurality of the first through-structures includes a barrier layer disposed on the lower interconnection structure and a conductive electrode disposed on the barrier layer.

18. A semiconductor package comprising:
a lower interconnection structure including a lower insulating layer and a lower interconnection layer including a ground pattern;
a lower semiconductor chip disposed on the lower interconnection structure;
an encapsulant on the lower interconnection structure and covering at least a portion of the lower semiconductor chip;
an upper interconnection structure disposed on the encapsulant and including an upper insulating layer and an upper interconnection layer;
a plurality of first through-structures disposed around the lower semiconductor chip between the lower interconnection structure and the upper interconnection structure, defining a first region on a plane; and
a plurality of second through-structures disposed around the first region between the lower interconnection structure and the upper interconnection structure and defining a second region on the plane,
wherein each of the plurality of second through-structures is in contact with the ground pattern of the lower interconnection layer and is spaced apart from the upper interconnection layer by a first distance in a vertical direction, and the second through-structures adjacent to each other are spaced apart from each other by a second distance on the plane.

19. The semiconductor package of claim 18, wherein the first distance and the second distance are a same distance.

20. The semiconductor package of claim 18, wherein the second region has a circular shape or a rectangular shape on the plane and the plurality of second through-structures form an electromagnetic interference shield.
